(19) United States
(12) Patent Application Publication
(10) Pub. No.: US 2025/0293092 A1
(43) Pub. Date: Sep. 18, 2025

(54) METHODS FOR SINGULATING SEMICONDUCTOR DIE FROM SILICON CARBIDE SUBSTRATES

(71) Applicant: SEMICONDUCTOR COMPONENTS INDUSTRIES, LLC, Scottsdale, AZ (US)

(72) Inventors: Ian Ceazar Bucayon BARIAS, Butuan City (PH); Shuai WANG, Suzhou (CN); ZhenLiang LU, SuZhou (CN)

(73) Assignee: SEMICONDUCTOR COMPONENTS INDUSTRIES, LLC, Scottsdale, AZ (US)

(21) Appl. No.: 18/606,922

(22) Filed: Mar. 15, 2024

(51) Int. Cl. H01L 21/78; H01L 21/04; H01L 21/268; H01L 21/683

(52) U.S. Cl. CPC H01L 21/78; H01L 21/0445; H01L 21/268; H01L 21/6836

(57) ABSTRACT

Implementations of a method of singulating silicon carbide may include providing a silicon carbide substrate including a thickness; in a plurality of X-direction die streets, irradiating the silicon carbide substrate with a laser beam at a focal point a depth into the thickness in a predetermined number of X-passes, each X-pass having a different laser spot diameter; and in a plurality of Y-direction die streets, irradiating the silicon carbide substrate in a Y-direction with the laser beam at a focal point a depth into the thickness in a predetermined number of Y-passes, each Y-pass having a different laser spot diameter. The method may include breaking the silicon carbide substrate first in the Y-direction and then in the X-direction using an anvil; and expanding a tape coupled to the silicon carbide substrate to separate a plurality of die from the silicon carbide substrate.

### BACKGROUND

### 1. Technical Field

Aspects of this document relate generally to systems and systems for singulating semiconductor die from semiconductor substrates. More specific implementations involve singulating semiconductor die from silicon carbide substrates.

### 2. Background

Semiconductor substrates are utilized for the purpose of creating various semiconductor devices thereon. Many different types of semiconductor devices have been devised, including transistors, diodes, rectifiers, and the like.

### SUMMARY

Implementations of a method of singulating silicon carbide may include providing a silicon carbide substrate including a thickness; and in a plurality of X-direction die streets: irradiating the silicon carbide substrate in an X-direction with a laser beam focused at a first focal point a first distance into the thickness in a first X-pass; irradiating the silicon carbide substrate in the X-direction with the laser beam focused at a second focal point a second distance into the thickness in a second X-pass; irradiating the silicon carbide substrate in the X-direction with the laser beam focused at a third focal point a third distance into the thickness in a third X-pass; and irradiating the silicon carbide substrate in the X-direction with the laser beam focused at a fourth focal point a fourth distance into the thickness in a fourth X-pass. The method may also include in a plurality of Y-direction die streets: irradiating the silicon carbide substrate in a Y-direction with the laser beam focused a first focal point a first distance into the thickness in a first Y-pass; irradiating the silicon carbide substrate in a Y-direction with the laser beam focused a second focal point a second distance into the thickness in a second Y-pass; irradiating the silicon carbide substrate in a Y-direction with the laser beam focused a third focal point a third distance into the thickness in a third Y-pass; irradiating the silicon carbide substrate in a Y-direction with the laser beam focused a fourth focal point a fourth distance into the thickness in a fourth Y-pass; irradiating the silicon carbide substrate in a Y-direction with the laser beam focused a fifth focal point a fifth distance into the thickness in a fifth Y-pass. The method may include breaking the silicon carbide substrate in the X-direction and in the Y-direction along the plurality of X-direction die streets and the plurality of Y-direction die streets, respectively, using an anvil; and expanding a tape coupled to the silicon carbide substrate to separate a plurality of die from the silicon carbide substrate.

Implementations of a method of singulating silicon carbide may include one, all, or any of the following:

The first distance in the first X-pass may be further into the thickness than the second distance in the second X-pass, the second distance in the second X-pass may be further into the thickness than the third distance in the third X-pass, and the fourth distance in the fourth X-pass may be further into the thickness than the third distance in the third X-pass.

The first distance in the first X-pass may be −26 microns, the second distance in the second X-pass may be −19 microns, the third distance in the third X-pass may be −13 microns, and the fourth distance in the fourth X-pass may be −14 microns.

The first distance in the first Y-pass may be further into the thickness than the second distance in the second Y-pass; the second distance in the second Y-pass may be further into the thickness than the third distance in the third Y-pass; the fourth distance in the fourth Y-pass may be further into the thickness than the third distance in the third Y-pass; and the fourth distance in the fourth-Y-pass may be further into the thickness than the fifth distance in the fifth Y-pass.

The first distance in the first Y-pass may be −26 microns, the second distance in the second Y-pass may be −21 microns, the third distance in the third Y-pass may be −13 microns, the fourth distance in the fourth Y-pass may be −17 microns, and the fifth distance in the fifth Y-pass may be −14 microns.

The scan speed used in the first Y-pass, the second Y-pass, the fourth Y-pass, and the fifth Y-pass may be 510 mm/second and a scan speed used in the third Y-pass may be 150 mm/second.

The scan speed used in the first X-pass, the second X-pass, and the fourth X-pass may be 525 mm/second and a scan speed used in the third X-pass may be 150 mm/second.

A laser power used in the first X-pass and the fourth X-pass may be 0.18 W; a laser power used in the second X-pass may be 0.12 W; a laser power used in the third X-pass may be 0.04 W; a laser power used in the first Y-pass, the second Y-pass, the fourth Y-pass, and the fifth Y-pass may be 0.23 W; and a laser power used in the third Y-pass may be 0.04 W.

Implementations of a method of singulating silicon carbide may include providing a silicon carbide substrate including a thickness; and in a plurality of X-direction die streets, irradiating the silicon carbide substrate in an X-direction with a laser beam focused at a focal point a distance into the thickness in four X-passes; and, in a plurality of Y-direction die streets, irradiating the silicon carbide substrate in a Y-direction with the laser beam focused a focal point a distance into the thickness in five Y-passes. The method may include breaking the silicon carbide substrate first in the Y-direction and then in the X-direction an along the plurality of X-direction die streets and the plurality of Y-direction die streets, respectively, using an anvil at a predetermined over travel height, an anvil distance of 0.39 mm, and a chopper drop speed of 20 mm/second; and expanding a tape coupled to the silicon carbide substrate to separate a plurality of die from the silicon carbide substrate at a temperature of 60 C.

Implementations of a method of singulating silicon carbide may include one, all, or any of the following:

When the thickness of the silicon carbide substrate is about 100 microns, the predetermined over travel height may be 1.23 mm for the X-direction die streets and 1.21 mm for the Y-direction die streets.

When the thickness of the silicon carbide substrate is about 200 microns, the predetermined over travel height may be 1.14 mm for the X-direction die streets and 1.12 mm for the Y-direction die streets.

Expanding the tape further may include expanding at an expansion height of 8 mm, an expansion speed of 10 mm/second, and a hold time of 30 seconds.

Implementations of a method of singulating silicon carbide may include providing a silicon carbide substrate including a thickness; and in a plurality of X-direction die streets, irradiating the silicon carbide substrate in an X-direction with a laser beam focused at a focal point a depth into the thickness in a predetermined number of X-passes, each X-pass of the predetermined number of X-passes having a different laser spot diameter; and in a plurality of Y-direction die streets, irradiating the silicon carbide substrate in a Y-direction with the laser beam focused a focal point a depth into the thickness in a predetermined number of Y-passes, each Y-pass of the predetermined number of Y-passes having a different laser spot diameter. The method may include breaking the silicon carbide substrate first in the Y-direction and then in the X-direction along the plurality of X-direction die streets and the plurality of Y-direction die streets, respectively, using an anvil; and expanding a tape coupled to the silicon carbide substrate to separate a plurality of die from the silicon carbide substrate.

Implementations of a method of singulating silicon carbide may include one, all, or any of the following:

In the X-direction, a first laser spot diameter of a first X-pass may be larger than a second laser spot diameter of a second X-pass and a third laser spot diameter of a third X-pass may be smaller than a fourth laser spot diameter of a fourth X-pass.

In the Y-direction, a first laser spot diameter of a first Y-pass may be larger than a second laser spot diameter of a second Y-pass, a third laser spot diameter of a third Y-pass may be smaller than a fourth laser spot diameter of a fourth Y-pass, and a fifth laser spot diameter of a fifth Y-pass may be smaller than the fourth laser spot diameter of the fourth Y-pass.

The first depth of a first X-pass may be −26 microns, a second depth of a second X-pass may be −19 microns, a third depth of a third X-pass may be −13 microns, and a fourth depth of a fourth X-pass may be 14 microns.

The first depth of a first Y-pass may be −26 microns, a second depth of a second Y-pass may be −21 microns, a third depth of a third Y-pass may be −13 microns, a fourth depth of a fourth Y-pass may be −17 microns, and a fifth depth of a fifth Y-pass may be −14 microns.

The fourth laser spot diameter of the fourth X-pass may generate a modified region in portions of the plurality of X-direction die streets not covered by a pattern.

The fourth laser spot diameter of the fourth X-pass may burn or melt at least a portion of a pattern present in portions of the plurality of X-direction die streets.

The first laser spot diameter, second laser spot diameter, and third spot diameter may generate a modified region in portions of the plurality of X-direction die streets covered by a pattern.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional diagram of an implementation of a silicon carbide substrate during irradiation with a laser beam in a die street;

FIG. 2 is another cross sectional diagram of a silicon carbide substrate during pulsed laser irradiation in a die street during feeding of the silicon carbide substrate;

FIG. 3 is a cross sectional view of an implementation of a breaking system;

FIG. 4 are side and top views of a silicon carbide substrate prior to and during expansion using an expansion system;

FIG. 5 is a flow diagram with corresponding diagrams of a silicon carbide substrate during processing with an implementation of a lasering system, breaking system, and expansion system;

FIG. 6 is a cross sectional view of a silicon carbide substrate showing the location into the material of the silicon carbide substrate for laser irradiation in various X-direction passes (X-passes) and various Y-direction passes (Y-passes);

FIG. 7 is a flow chart of an implementation of a method of singulating silicon carbide;

FIG. 8 is a diagram of die samples used in three-point bending testing and an illustration of a three-points bending testing systems;

FIG. 9 is a cross sectional view of an implementation of a breaking system and a detail view of the tip of an implementation of an anvil during operation;

FIG. 10 illustrates a sequence of processing steps for a silicon carbide substrate during an expansion process;

FIG. 11 is a top-down photomicrograph of an X-axis die street following lasering;

FIG. 12 is a diagram of a die street during lasering through a pattern in the die street;

FIG. 13 is a diagram showing the change in laser spot diameter corresponding with a change in depth of a focal point into a thickness of a silicon carbide substrate; and

FIG. 14 a top down photomicrograph of a pattern in a die street prior to lasering;

FIG. 15 is a top down photomicrograph of the pattern of FIG. 14 following a first pass;

FIG. 16 is a top down photomicrograph of the pattern of FIG. 15 following a second pass;

FIG. 17 is a top down photomicrograph of the pattern of FIG. 16 following a third pass;

FIG. 18 is a photomicrograph of a sidewall of a silicon carbide substrate showing modified regions where a pattern is absent and under a pattern in the die street;

FIG. 19 is a diagram of the effect of laser spot diameter on a pattern in a die street during three passes; and

FIG. 20 is a diagram of the effect of laser spot diameter on a pattern in a die street during four passes.

### DESCRIPTION

This disclosure, its aspects and implementations, are not limited to the specific components, assembly procedures or method elements disclosed herein. Many additional components, assembly procedures and/or method elements known in the art consistent with the intended methods of singulating semiconductor substrates will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such method of singulating semiconductor substrates, and implementing components and methods, consistent with the intended operation and methods.

The various methods of singulating semiconductor substrates disclosed herein utilize focused laser irradiation to form a damaged/modified region in the interior of the semiconductor substrate followed by breaking of the semiconductor substrate along the modified region and separation of a plurality of die from the semiconductor substrate using a tape expansion process. This overall process is referred to as “stealth dicing.” The stealth dicing process utilizes a lasering system, a breaking system, and an expansion system in combination with a substrate mounting system. While stealth dicing works in theory, the ability to use the process to accurately and repeatably singulate die from semiconductor substrates that can be included in semiconductor packages that can pass reliability testing involves significant experimentation that is semiconductor substrate material dependent. The semiconductor substrate material dependence is also a function of the specifications of the particular semiconductor substrate material which may include, by non-limiting example, semiconductor material type, crystallographic orientation, crystal plane alignment to surface, dopant concentration, dopant type, number of crystal imperfections/defects, type of crystal imperfections/defects, orientation of crystal imperfections/defects, semiconductor substrate thickness, semiconductor substrate size, die street orientation (X or Y), and many other attributes/parameters of a semiconductor substrate material.

Because of this, attempting to use stealth dicing parameters used for one semiconductor substrate type for a process of stealth dicing another semiconductor substrate type, or even for a different thickness of the same semiconductor substrate type, does not yield predictable results. Because of this, the significant experimentation detailed in this document was involved in developing a stealth dicing process specific to a particular semiconductor substrate material—in this case, silicon carbide. The results in this document obtained through experimentation were unpredictable and unexpected. Because of the extreme hardness of silicon carbide, dicing of the semiconductor substrate is slow and difficult using sawing with diamond coated/impregnated saw blade technology. The ability to utilize stealth dicing to produce die from a silicon carbide substrate that are capable of being included in packages that pass reliability tests may be very valuable. Such a process may increase the wafer per hour and units per hour that can be processed in a packaging/assembly process. Such a process may also allow for a shrinking of the die as the width of the die streets can be reduced because the die street width no longer needs to accommodate the kerf width of a given saw blade.

The silicon carbide substrates disclosed in the examples herein are N-type, 4H polytype, with a crystal orientation of 4 degrees off axis. The dislocation density of the silicon carbide substrates is about 5×10³ cm² with a micropipe density of less than 0.1 cm². The principles disclosed herein could also be applied to silicon carbide substrates with different dislocation densities and micropipe densities as well.

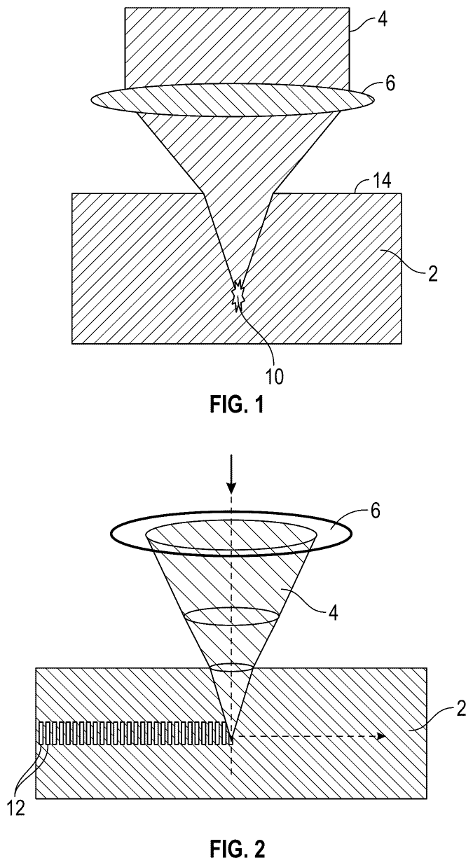

Referring to FIG. 1, a cross sectional diagram of an implementation of a silicon carbide substrate 2 during irradiation with a laser beam 4 in a die street using a lasering system. As illustrated, a lens 6 (or group of lenses) is used to focus the laser irradiation 4 onto/into the material of the silicon carbide substrate 2. As illustrated, as the focused laser beam 4 enters the material of the silicon carbide substrate 4, it is refracted at an angle 8 determined by the material and the particular wavelength/energy of the irradiation of the laser beam 4. The combination of the focus applied by the lens 6 and the refraction angle 8 determines the depth/location into the material of the silicon carbide substrate 2 at which the focal point 10 of maximum energy of the laser beam 4 is located. In FIG. 1, the laser beam 4 is traveling in a direction perpendicular with the paper (into and out of the paper). At the focal point 10, the energy of the focused irradiation of the laser beam 4 modifies the material of the silicon carbide substrate at the focal point to create a modified region.

While in FIG. 1 the focal point 10 is represented as a point, in actual fact, the absorption of the energy of the irradiation from the laser beam 4 occurs in a more linear direction (in the form of a column/cylinder) in the direction of the laser beam into the material. Since the laser beam is operated in a pulsed mode rather than in a continuous wave mode, when the silicon carbide substrate 2 is fed/scanned at a fixed rate under the laser beam 4, a pattern of modified regions 12 corresponding with each focused pulse of the irradiation of the laser beam 4 can be observed in cross section, as illustrated in diagram of FIG. 2. Depending upon the overlap of each pulse with each other pulse set by the pulse repetition rate and/or feed speed of the silicon carbide substrate 2, the modified regions 12 may be present in the material of the silicon carbide substrate 2 as separated by unmodified material (as illustrated in FIG. 2) or may blend into one another to form a continuous/substantially continuous modified region. In this document, the terms “modified region” and “modified layer” are used synonymously for this reason.

The depth into the material of the silicon carbide substrate 2 of the focal point 10 can be adjusted using the lens 6 and/or altering the physical distance between the lens 6 and the top surface 13 of the silicon carbide substrate 2. Where multiple passes of the laser beam across the silicon carbide substrate 2 are used, the depth of each pass can be independently set to be the same, deeper into, or closer to the top surface 13 of the silicon carbide substrate 2 as the previous pass. Here the term “top surface” 13 refers to the surface of the silicon carbide substrate that faces the laser beam 4. The top surface could be either the side of the silicon carbide substrate that contains electrically active devices (active side) of the silicon carbide substrate, or the opposing surface of the silicon carbide substrate (backside) in various method implementations.

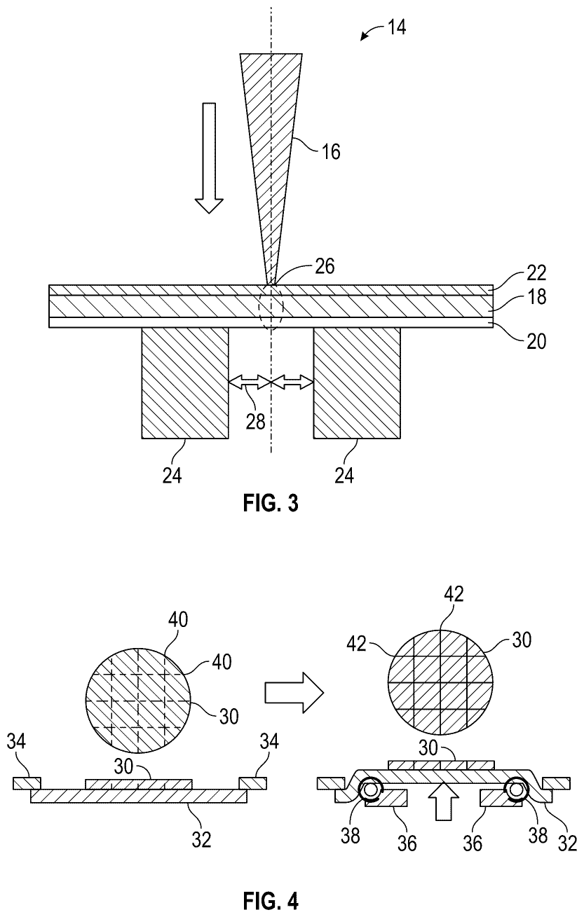

The various method implementations disclosed herein also employ two other major processes to achieve separation of the various die from the silicon carbide substrates, breaking, and expansion. Referring to FIG. 3, an implementation of a breaking system 14 is illustrated. Here the breaking system 14 includes a chopper 16 that is illustrated above substrate 18 upon which cover tape 20 and mounting tape 22 have been coupled on either side. Here the chopper 16 is positioned equidistant between portions of anvil 24 spaced apart by anvil distance 28 on each side to create a bending moment in the substrate 18 when the chopper is pressed down against the mounting tape 22. Determining the distance the chopper 16 should travel down against the mounting tape 22 during operation to produce a clean and repeatable breaking of the silicon carbide substrate at the modified region(s)/layer(s) in the die street is the result of several calibrations and calculations that involve the thickness of the cover tape 20, the thickness of the mounting tape 22, and the thickness of the silicon carbide substrate 18.

In a particular method implementation, a calibration of a chopper absolute height is performed by placing just cover tape over the anvil and lowering the chopper until the cover tape just reaches a point where it cannot be pulled out from underneath the chopper. In a particular implementation where the chopper is 91.34 mm long/high the chopper absolute height becomes 91.378 mm where the thickness of the cover tape is 0.038 mm. In various method implementations, a chopper over travel height is used to describe a distance that the chopper travels from a zero point of the drive motor to the surface of the silicon carbide substrate (which would be through the thickness of the mounting tape if present). To help take into account the thickness of the mount tape, cover tape, and substrate thickness for a given absolute chopper over travel height, a parameter called relative height by wafer is calculated and was varied in the experiments disclosed in this document.

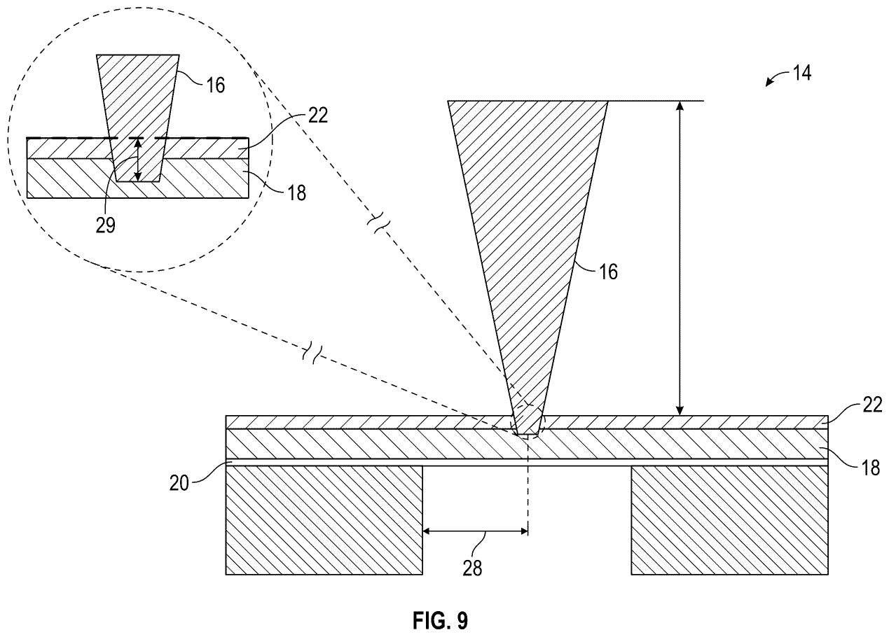

In a particular implementation with the previous specified chopper height, cover tape thickness, and for a 200 micron thick silicon carbide substrate the calculation for relative height by wafer is done by adding the silicon carbide substrate thickness, chopper over travel height, mounting tape thickness, cover tape thickness together and then subtracting 1378 microns. The result for a mounting tape thickness of 90 microns, cover tape thickness of 50 microns, chopper absolute over travel height is 1.14 mm, chopper absolute height of 91.14 mm is a chopper relative height by wafer of 102 microns. Referring to the larger view of the breaking system of FIG. 3 illustrated in the cross sectional view of FIG. 9, this chopper relative height by wafer 29 reflects the distance that the chopper pushes below the original level of the silicon carbide substrate 18 beneath the mounting tape 22 during downward deflection above the anvil 24 at the contact location 26. In other words, the chopper relative height by wafer 29 is a reflection of the amount of force that needs to be applied to the mounting tape/silicon carbide substrate/cover tape stack to achieve breaking of the silicon carbide substrate at a given anvil distance. In the studies in this document, the relative height by wafer 29 and actual anvil distance 28 demonstrated statistical significance when the occurrence of undivided die and presence of lateral cracks was assessed. In the study, a process window of relative height by wafer of between about 134 microns to about 144 microns and an X axis anvil distance between the chopper and the side of the anvil of about 3108 microns to about 3260 microns was identified as producing acceptable results with respect to both undivided die and presence of lateral cracks. In the Y axis direction, a relative height by wafer of between about 102 microns to about 120 microns at a Y axis anvil distance of about 2628 microns was identified as producing optimal results for undivided die (no effect on lateral cracking in the Y axis was identified in the study.

Following breaking of the die, since the die in a stealth dicing process are only separated by the actual width of the actual crack between the die, the ability to pick the die from the mounting tape without causing die chipping is low. To increase the ability for die picking to occur successfully post-breaking, the mounting tape is stretched/expanded using an expansion system. Referring to FIG. 4, a mounted silicon carbide substrate 30 is illustrated coupled to mounting tape 32 and frame 34 in a top down and in a side cross sectional view on the left. Here the broken lines 40 in the silicon carbide substrate 30 are represented as dotted lines because they are difficult to see visually because the very small width of the breaks. On the right, FIG. 4 illustrates the silicon carbide substrate 30 following an expansion process using a chuck that rises up a predetermined height/distance underneath the mounting tape 32 and contains rollers 38 that assist the tape with stretching uniformly across the width of the silicon carbide substrate 30. The goal of the tape expansion process is to produce sufficiently wide spaces 42 between the die to allow a die picking process to remove the singulated die from the tape without die chipping where the tape is not stretched too much to cause the die to sag during picking, thus hindering picking accuracy. The process variables that help assist with the expansion process include the height the chuck rises (expansion height), the temperature the expansion is carried out at, the time the tape is held by the chuck in the expansion position (hold time), and the speed the chuck rises (expansion speed). Following the expansion process, the mounted silicon carbide substrate is then moved to a die picking operation where the singulated die can then be picked and placed either directly onto a package substrate or in a picking tape that for subsequent use in a package assembly process.

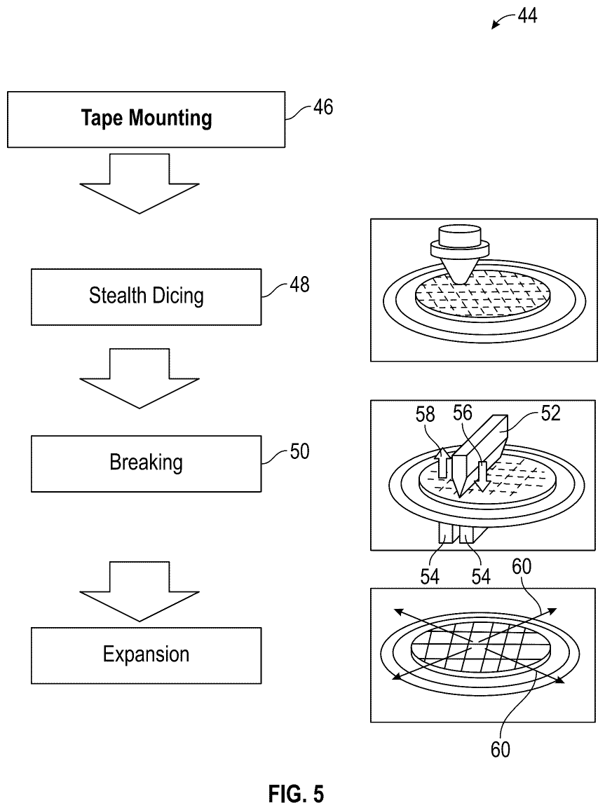

Referring to FIG. 5, a flow diagram of an implementation of a method of stealth dicing a silicon carbide substrate 44 is illustrated. As illustrated in FIG. 5, a tape mounting process (step 46) is used to apply a mounting tape and/or a cover tape prior to stealth dicing. In some method implementations, no tape may be present on the top surface of the silicon carbide substrate; in others, a tape (cover or mounting) may be applied to the top surface. Following the tape mounting process, the stealth dicing process (step 48) is carried out. As disclosed later this document, the stealth dicing process may involve multiple passes in the X-axis scribe lines/die streets (X-passes) and multiple passes in the Y-axis scribe lines/die streets (Y-passes) using a laser and lens. The laser and lens operate at a given wavelength and laser power. While the term “laser power” is used in this document, since the laser may be operated in pulsed mode, the “laser power” is a time averaged calculation of the average power of the set of pulses being produced by the laser in contrast with a constant output power from a laser operating in continuous wave mode.

Following the stealth dicing process, the silicon carbide substrate is then processed using the breaking system (step 50) which includes chopper 52 and anvil 54 which may be any disclosed in this document. As illustrated in FIG. 5, the breaking process employs the downward force 56 applied by the chopper 52 in combination with the corresponding moment 58 supplied by the two portions of the anvil spaced apart by the anvil distance which work to cause the substrate to break along the entire line of the chopper in the die street area of the silicon carbide substrate.

Following the breaking process, the mounted silicon carbide substrate is then processed by an expansion system which works to expand the substrate from the center point outward indicated by the four arrows 60 in FIG. 5. The result of the expansion system is to create sufficient spaces between the die to allow a die picking apparatus to allow a die picking apparatus to remove the various die without die chipping or issues caused by the sagging of overly stretched tape. The ability to do the expansion at a higher temperature than the picking process may allow the tape to deform plastically during the stretching process but then regain tensile strength for the picking process when it cools.

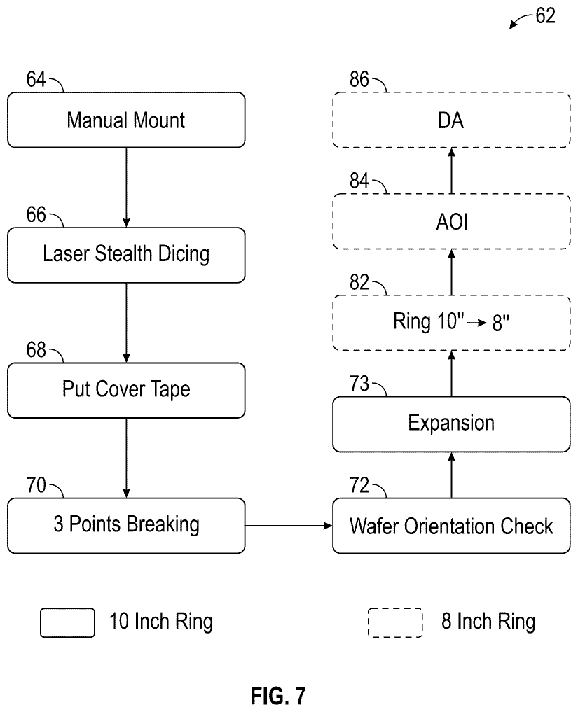

Referring to FIG. 7, a flow chart of another implementation of a method of singulating a silicon carbide substrate 62 is illustrated. In this implementation, a manual tape mounting process is employed (step 64) though in other implementations an automatic tape mounter may be used. Any laser stealth dicing process disclosed herein is them employed (step 66), followed by application of a cover tape to the back side of the silicon carbide substrate (the side that did not face the laser during lasering (step 68). The application of the cover tape may be done either manually or automatically using an automatic tape mounter in various method implementations. The silicon carbide substrate is then ready for processing using a breaking system like any disclosed herein (three points breaking process, step 70).

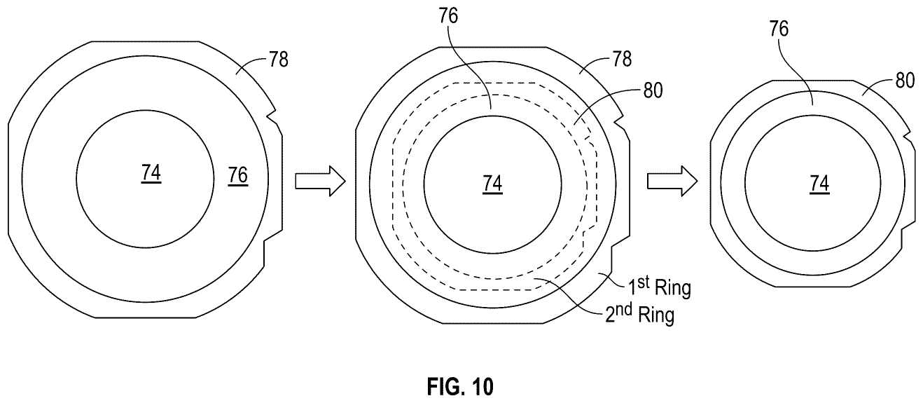

As illustrated in FIG. 7, the method includes a check of the orientation of the silicon carbide substrate (wafer orientation check, step 72) to ensure the wafer flat(s) (or other orientation structures) is in the proper orientation as the silicon carbide substrate is loaded onto the expansion system. This process ensures that the die streets are properly oriented relative to the expansion forces that will be applied as the chuck is raised underneath the during the expansion forces. This helps ensure uniform/desired spacing in between the die following the expansion process. The silicon carbide substrate then undergoes the expansion process which may any disclosed in this document (step 73). In a particular method implementation, with reference to FIG. 10, a remounting process (step 82) may be utilized. In various implementations, by non-limiting example, the original size of the silicon carbide substrate 74 is a six inch diameter mounted using mounting tape 76 to a ten inch diameter frame/ring 78. In this implementation, following the expansion process, a second eight inch ring 80 is applied to the mounting tape 76 while the silicon carbide substrate 74 is still mounted and the first ring 78 is then removed in a second mounting process. During this process, the now stretched mounting tape is tightened as it is applied to the second ring 80, which can further prevent drooping/sagging during subsequent die picking processing. The silicon carbide substrate 74 is then processed during subsequent steps while attached to the second ring 80. As indicated in FIG. 7, those process steps with solid line outlines are those done with the first ring and those in dotted lines are those performed with the second ring in place.

These additional process operations may include, as illustrated in FIG. 7, an automated optical inspection (AOI, step 84) followed by a die picking operation that occurs either simultaneously with or prior to a die attach process where each die is attached to a substrate during a die packaging operation (DA, step 86).

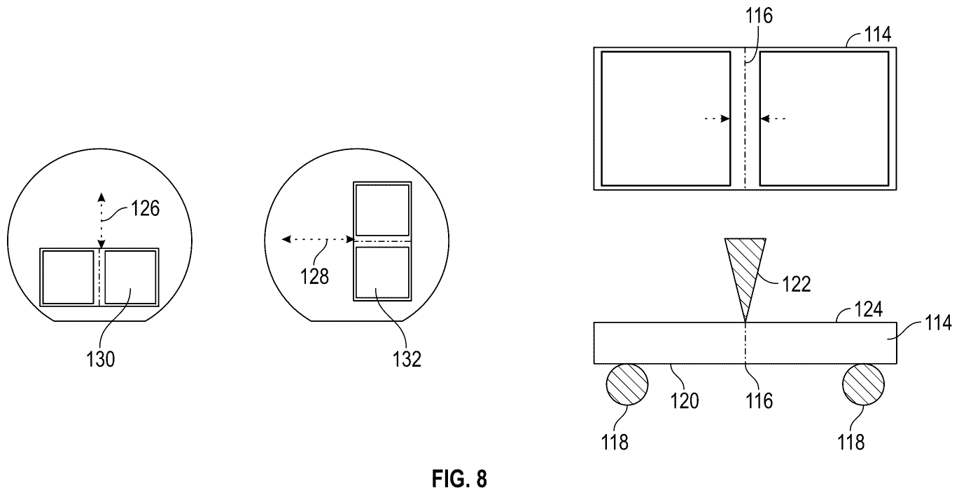

The breaking strength of the die at the die streets following stealth dicing was also measured using a three-point bending testing technique. This three-point bending technique was used to collect data that is different from ordinary die strength data collected using three-point bending. In ordinary die strength data collection, a single die is subjected to the three-point bending to assess the die's strength following thinning and/or singulation. In the testing done here, referring to FIG. 8, two die 114 were singulated from a silicon carbide substrate following stealth dicing between the two die 114 but without breaking being carried out in the die street 116 between the two die. The two die were then placed onto two supports 118 spaced on each side of the die street with the front (active) side 120 of the two die 114 in contact with the two supports 118. A chopper 122 is then placed against the back side (124) of the two die 114 at the die street 116 and then pressed against the back side 124 until the two die break at the die street 116. As illustrated in FIG. 8, the breaking strength of the die streets 126 in the Y direction was tested using two die 130 and the breaking strength of the die streets in 128 in the X direction was tested using two die 132. In a particular implementation, the breaking strength for 100 micron thick silicon carbide die was observed to be on the average higher in the Y direction die streets than in the X direction die streets by about 1 Newton.

Various process parameters for the various stealth dicing method implementations are disclosed in this document. These are exemplary and reflect the results of sets of statistically designed experiments including reliability testing of assembled die to validate that the singulation processes provide long-term stability for a desired design lifetime.

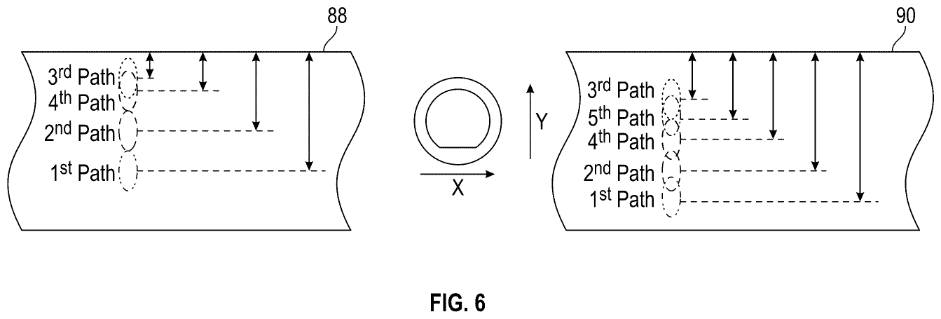

Referring to FIG. 6, a diagram of the laser passes in an implementation of a lasering process with multiple passes in the X direction 88 and in the Y direction 90 is illustrated. Here, four passes in each X die street are conducted and five passes in each Y die street are carried out. FIG. 6 indicates that in this particular method implementation, the four passes in the X die streets are carried out where the first path is at a first deepest distance into the material of the silicon carbide substrate (first depth), the second path is at a second distance into the material of the silicon carbide substrate (second depth) that is not as deep as the first, the third path is at a third distance into the material of the silicon carbide substrate (third depth) that is less deep than the second, and the fourth path is at a fourth deepest distance into the material of the silicon carbide substrate (fourth depth) that is deeper than the third distance/depth. Put differently, the first path in the X direction is further into the thickness of the silicon carbide substrate than the second path, the second path is further into the thickness than the third path, and the fourth path is further into the thickness than the third path. In this implementation, the fourth path is less deep than the depth of the second path. The reasons for this difference in the depth of the third path and the presence of the fourth path will be discussed hereafter.

In the Y direction, as illustrated, the five paths are carried out where the first path is at a first deepest distance into the silicon carbide substrate and the second path is a second less deep distance into the silicon carbide substrate. The third path is at third, least deep distance into the silicon carbide substrate. The fourth path is at a fourth distance less deep than the second path, and the fifth path is at a fifth distance less deep than the fourth path but deeper than the third distance of the third path. Put differently, the first distance of the first Y-pass is further into the thickness of the silicon carbide substrate than the second distance of the second Y-pass, the second distance is further into the thickness than the third distance of the third Y-pass, the fourth distance of the fourth Y-pass is further into the thickness than the third distance, and the fourth distance in further into the thickness than the fifth distance of the fifth Y-pass. These same paths in these relative distances and orders can be employed for both 100 micron thick silicon carbide substrates and 200 micron thick silicon carbide substrates.

The effect of the multiple passes is to create modified regions/layers within the thickness of the silicon carbide substrate. The modified regions/layers work to assist with propagating cracking through the thickness and along the length of each X street and Y street of the silicon carbide substrate. Provided adequate modified region/layers are present, during the breaking operation, the crack that singulates the die propagates in a controlled fashion along the modified region/layers along each die street. In contrast, uncontrolled propagation of the crack can allow the crack to leave the die street region and move into the active areas of the die surrounding the die street in the form of lateral cracks. The uncontrolled cracking is noted primarily by die failures post singulation as the uncontrolled cracked portions of the die damage it in ways that prevent it from working properly thereafter.

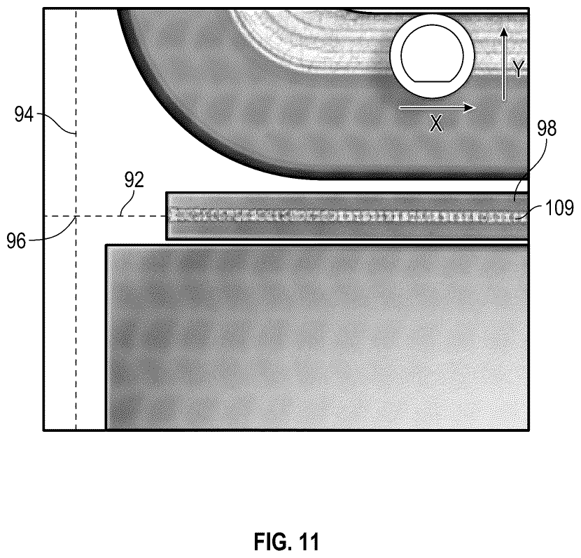

The presence of modified regions/layers in the thickness of the silicon carbide substrate is difficult to see from a top down visual microscope inspection, and so the location of these regions are indicated in FIG. 11 with drawn dotted lines that overlay the photomicrograph of an implementation of four die of a silicon carbide substrate. This silicon carbide substrate is like any disclosed in this document. Here the dotted lines show the location of the as-lasered X die street 92 and the as-lasered Y die street 94 at die intersection 96. What is visually perceptible in FIG. 11 in the X die street 92 is a pattern 98 formed in the die street. The pattern 98 in various implementations is made of any of a wide variety of die stack materials that are different from the silicon carbide/oxide/passivation materials present elsewhere in the die street, including, by non-limiting example, metals, metal alloys, or underbump metallization material. These materials absorb the laser light more completely than the other silicon carbide/oxide/passivation materials in the die street, preventing more laser light from reaching focal point of the laser beam into the thickness. They also absorb visually perceptible light and so appear differently colored in the photomicrograph.

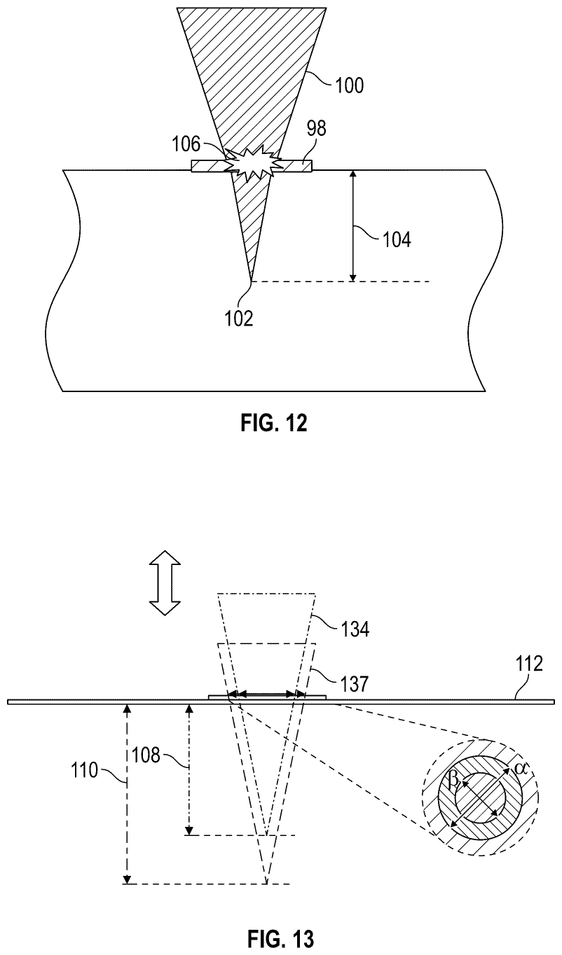

FIG. 12 is a diagram illustrating the effect of the pattern 98 on the uniformity of the laser beam 100 as the laser beam tries to reach the focal point 102 at the desired depth 104. As illustrated, the additional absorption of the light in the laser beam 100 reduces the amount of light that is then able to reach the focal point 102. If the absorption of the light is sufficient (as in a situation where the laser beam is being emitted at a sufficiently high power), FIG. 12 shows how burning/melting 106 of the material of the pattern 98 is taking place. One of the challenges presented by the burned/melted material 106 is that it generally is now more absorbent or reflective of the laser light than the material of the pattern 98 was originally. In other words, a second pass of laser light over the burned/melted material 106 will now be even more attenuated at the focal point 102 than the pass in which the burned/melted material 106 was formed originally. If the power of the laser beam in the second pass is sufficiently high to create more burned/melted material in the second pass, then the pattern 98 becomes even more absorbent of laser light in a third pass than it was in the second pass. Thus, the ability of the laser beam to create the desired modified region/layer in the silicon carbide substrate below the pattern is additionally reduced. FIG. 11 shows a burn/melting pattern 109 on the material of underlying pattern. The stippled/alternating pattern in the burn/melting pattern 109 reflects that the laser used to do stealth dicing is a pulsed laser like those disclosed in this document.

The degree of burning/melting and/or the rate of burning/melting is a function of the laser spot diameter. The smaller the laser spot diameter, the higher the laser power density, and the more rapidly the burn/melting will take place at the same laser power. Referring to FIG. 13, a diagram of the relationship between laser spot diameters α and β and the corresponding laser focus height 110 and 108, respectively, is illustrated. Here, laser spot diameter α is the widest which occurs when the focus height 110 is deepest into the material of the silicon carbide substrate 112. Laser spot diameter β is narrower, which occurs when the focus height 108 is shallower into the material of the silicon carbide substrate. For the same laser beam power, the laser power density of laser spot diameter β is highest. Since the laser focus height changes by moving the laser len(ses) up or down, the lens focal length does not change during this movement, keeping the shape of the laser beams 134, 137 the same.

Equation 1 is a relationship that describes the laser power density (I₀) in gigawatts/cm² as a function of laser energy (E) in Joules, pulse duration (τ) in nanoseconds, the laser absorption rate (γ, %), the laser power (P) in gigawatts, and the laser spot diameter (d) in centimeters.

$${I}_{0} = \frac{4 γ E}{πτ {d}^{2}} = \frac{4 γ p}{π {d}^{2}} \qquad Equation 1$$

By inspection it is apparent that as the laser absorption rate γ increases due to changes in the material exposed to the laser (through burning/melting), the laser power density correspondingly increases. Also, the laser power density increases as the inverse square of the laser spot diameter, meaning that the strongest effect on laser power density is the effect of shifting focus height upward which reduces the laser spot diameter. Thus, the effect of decreasing the laser spot diameter is that the burning/melting worsens for the same laser power due to the marked increase in laser power density.

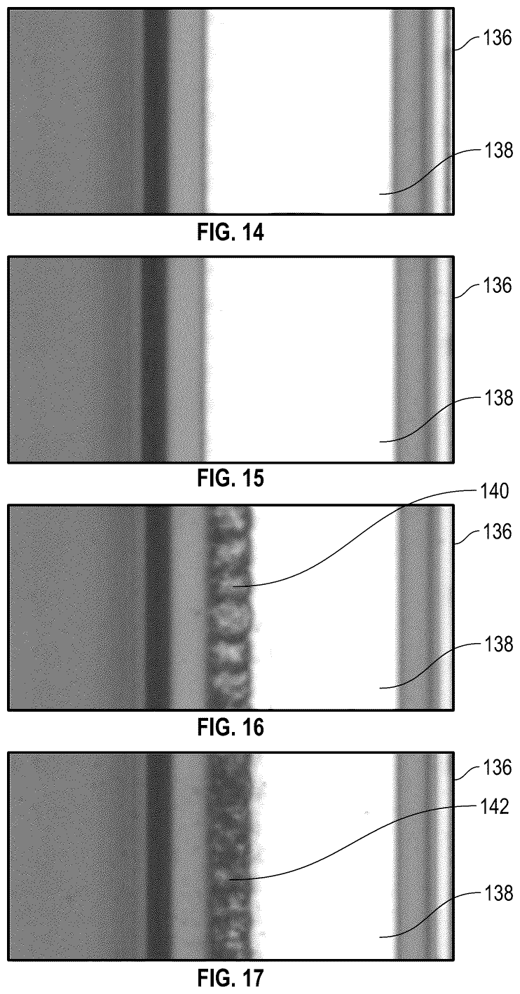

An experiment was done to study the effect of laser spot diameter on a silicon carbide substrate 136 that contained a pattern region illustrated in the photomicrograph of FIG. 14. Here the pattern 138 appears as a brighter region due to its higher reflectivity of optical light. FIG. 14 illustrates the silicon carbide substrate 136 prior to any lasering. A first pass of laser with a laser power of 0.18 W at a focus height of 26 microns was then carried out, and the resulting effect on the left edge of the pattern is illustrated in the photomicrograph of FIG. 15. Little or no visually perceptible effect at this laser spot diameter can be observed. A second pass of laser with a laser power of 0.18 W and a focus height of 19 microns was then carried out. The photomicrograph of FIG. 16 illustrates that at this laser spot diameter, a significant visually apparent burned/melted region 140 is now present in the pattern 138 of the silicon carbide substrate 136. A third laser pass with a laser power of 0.18 W and a focus height of 13 microns was then carried out, and the results illustrated in the photomicrograph of FIG. 17. Here the burned/melted region 142 is now even darker, reflecting that the burned/melted region 142 has, in addition to experiencing burning/melting from the smaller laser spot diameter, enhanced the laser absorption rate for the wavelength of the energy of the laser beam itself due to the change in the nature of the material in the burned/melted region 142. Thus, the amount of laser light anticipated to have reached the focal point at the focus height is reduced even more than would have been expected in the second laser pass. Thus the additive effect of melting/burning of the pattern 138 can cause one or more laser passes to fail to substantially create a modified region/layer within the silicon carbide, making the odds of uncontrolled cracking increased during the breaking operation. The effect of this viewed using photomicrographs or scanning electron microscopy of the sidewalls of the singulated die is that one or more of the passes can be “missing” or as having failed to modify the material of the silicon carbide substrate to show as having created a modified layer.

In the system and method implementations disclosed herein, the laser parameters have been optimized to comprehend the presence of a pattern in the X-direction die streets. A corresponding pattern was not present in the Y-direction die streets in these experiments. However, the principles disclosed herein regarding the modification of the laser parameters to handle the pattern in the X-direction die streets could be applied to help modify the laser parameters in the Y-direction die streets correspondingly, though appropriate experimentation would need to be done to validate the lasering and breaking parameters as disclosed herein. Also, while the use of four laser passes in the X-direction was noted to minimize yield losses as the result of the presence of the pattern in localized areas in the X-direction die streets, a complete elimination of yield losses due to uncontrolled breaking was not achieved. This indicates the difficulty the pattern creates in promoting the creation of lateral cracks and die cracks. The removal of the pattern would eliminate such failures, but would result in an inability to carry out other essential manufacturing functions like electrical test, die sorting, and other metrology operations typically carried out in the die street region. Furthermore, the need for/use of guard bands/structures where the lasering rested partly or fully on the guard band materials would create a need to develop laser parameters that comprehended the pattern of the guard bands/structures.

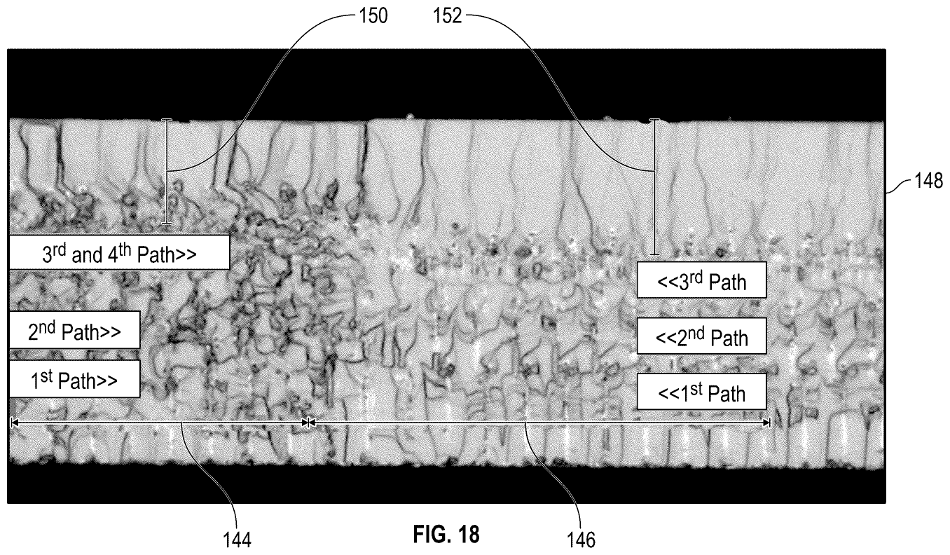

FIG. 18 is a photomicrograph of the sidewall of a singulated silicon carbide die with a total thickness of about 100 microns after lasering using the four X-pass process disclosed in this document (see FIG. 6 for a diagram). Here, across distance 144, which corresponds to a portion of the X-direction die street that does not have any pattern on it, the presence of modified layers corresponding the first path, second path, and third and fourth paths (which are located about 1 micron apart in depth) can be observed. Across distance 146 located under a pattern not visible in this cross section view, however, the presence of a modified layer corresponding with the fourth path does not substantially appear, and the degree of modification of the material for each of the three paths is reduced. Interestingly, the location of the modification layer induced by the three paths also appears to be slightly deeper into the thickness of the silicon carbide die 148 as the depth 150 above distance 144 measured about 27.26 microns while the depth 152 above distance 146 measured about 34.63 microns. The lower degree of modification observed and the lack of modification from the fourth path mean that propagation of a crack into the material under the pattern along distance 146 will be slightly different from the propagation under the distance 144. However, if the degree of modification under the pattern is sufficient, the propagation along distance 146 can be achieved reliably to minimize yield losses due to uncontrolled cracks and lateral cracks. Furthermore, the use of the fourth path helps ensure that sufficient modification occurs in those parts of the die street not under the pattern, further encouraging the material under the pattern to propagate the crack occurring through the other silicon carbide material. The various experiments disclosed in this document were designed to help ascertain the otherwise unpredictable laser parameters and other parameters that would help maximize the yield despite the presence of the intermittently present pattern in the X-direction die streets.

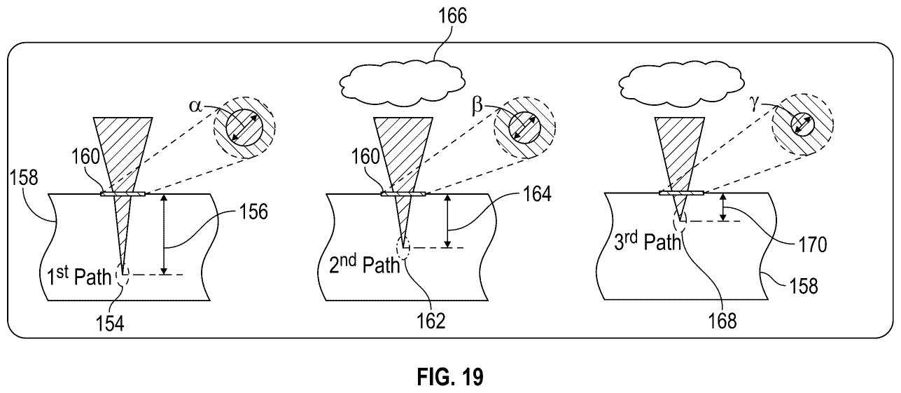

The effect of the change in laser spot diameter observed in FIGS. 14-17 is illustrated in the diagram of FIG. 19, which shows a three pass process at a consistent laser power pass-to-pass. As illustrated the first pass/path has the focal point 154 which is at the deepest depth 156 into the material of the silicon carbide substrate 158, creating a laser spot diameter of a on the pattern 160. No burning/melting occurs to the pattern 160 during processing of this first path. However, with the movement of the focal point 162 to depth 164, the laser spot diameter narrows to B. The resulting increase in laser power density results burning/melting of the pattern 160 represented by cloud 166. Because the pattern 160 is now at least partially burned/melted, enhanced burning/melting of the pattern 160 occurs when the focal point 168 shifts upwardly to depth 170, reducing the laser spot diameter to γ. This increase in absorption due to burning and the increase in laser power density can cause the entire loss of modification to the crystal structure of the silicon carbide substrate 158 from a pass/path. This diagram illustrates how use of the same laser power in each pass/path while sequentially reducing the laser spot diameter enhances burning/melting of the material of the pattern 160 and reduces formation of the modified region/layer under the pattern.

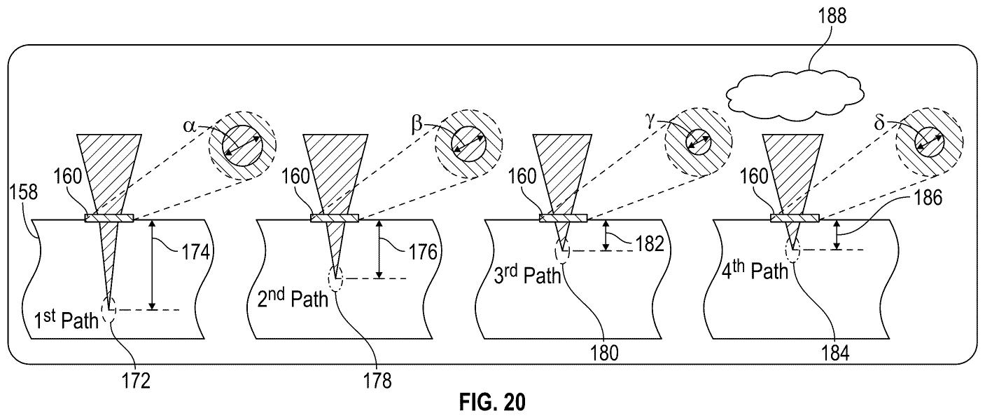

The diagram of FIG. 20 illustrates the effect of a four path/pass process where the first path/pass is carried out at a deepest focal point 172 at depth 174 with a laser spot diameter of a. No damage to the material of pattern 160 is observed at this pass which occurs at a first laser power level. During a second pass/path, the laser power is reduced and the depth 176 of the focal point 178 is also reduced, creating a laser spot diameter of B. Because of the reduction of the laser power, the laser power density that results at the smaller laser spot diameter β does not result in damage to the material of pattern 160. In the third path/pass, the focal point 180 is located at a further reduced depth 182, reducing the laser spot diameter to γ and the laser power is further reduced to a lowest power level. Again, the resulting laser power density does not result any damage to the pattern 160. During the fourth path/pass, the focal point 184 is moved to a depth 186 slightly lower than the depth 182 but at the same power as the first path at a laser spot diameter of 8. As illustrated, this higher laser power density than in any of the other passes results in burning/melting of the pattern 160 represented by cloud 188, but ensures that the material of the silicon carbide substrate 158 that is not under the pattern gets a significant exposure to modifying laser energy to assist with smooth creation of a crack that can propagate into the area under the pattern 160 as previously discussed. Thus the burning/melting in the final pass of the pattern 160, while affecting the modification of the silicon carbide substrate material under the pattern, does not as fully attenuate the laser energy like the third pass through already burned/melted material illustrated in FIG. 19.

Various statistically designed experiments were conducted with 100 micron thick silicon carbide substrates like those disclosed herein to determine those factors that affected stealth dicing and breaking quality/capability. The results of various of these experiments are reported in summary form in this document for the purposes of disclosing the ranges of operating parameters where the best results were achieved. These results are also applicable to 200 micron thick silicon carbide substrates though these were not used in the testing.

In the experiments, an initial set of lasering, breaking, and expansion parameters was used as a starting point which was the result of significant factorial experimental design work on the various parameters. These parameters are found in Tables 1, 2, 3, and 4 below:

Table 1 includes the set of initial lasering parameters used for both 100 micron thick and 200 micron thick silicon carbide substrates:

TABLE 1

| | | | Focus | Scan | | | Laser | Focus | Scan |
|---|---|---|---|---|---|---|---|---|---|
| | | | Height | Speed | | | Power | Height | speed |
| Path | Wavelength | Power (W) | (um) | (mm/s) | Path | Wavelength | (W) | (um) | (mm/s) |
| X0 | 1064 nm | 0.18 | −26 | 525 | Y0 | 1064 nm | 0.23 | −26 | 510 |
| X1 | 1064 nm | 0.18 | −19 | 525 | Y1 | 1064 nm | 0.23 | −21 | 510 |
| X2 | 1064 nm | 0.18 | −13 | 525 | Y2 | 1064 nm | 0.04 | −13 | 150 |
| | | | | | Y3 | 1064 nm | 0.23 | −17 | 510 |
| | | | | | Y4 | 1064 nm | 0.23 | −14 | 510 |

Table 2 includes the set of initial breaking parameters for use with the breaking system for about 100 micron thick silicon carbide substrates. The breaking sequence involves breaking the Y direction streets first followed by breaking the X direction streets second.

TABLE 2

| | Over Travel Height | Anvil Distance | Chopper Drop |
|---|---|---|---|
| Direction | (mm) | (ratio multiplier) | Speed (mm/s) |
| X | 1.2 | 0.39 | 20 mm/s |
| Y | 1.2 | 0.39 | 20 mm/s |

Table 3 includes the set of initial breaking parameters for use with the breaking system for about 200 micron thick silicon carbide substrates. The breaking sequence involves breaking the Y direction streets first followed by breaking the X direction streets.

TABLE 3

| Direction | Over Travel Height | Anvil Distance | Chopper Drop |
|---|---|---|---|
| (see FIG. 6) | (mm) | (ratio multiplier) | Speed (mm/s) |
| X | 1.12 | 0.39 | 20 mm/s |
| Y | 1.12 | 0.39 | 20 mm/s |

Table 4 is the set of initial expansion parameters for use with the expansion system for both about 100 micron and about 200 micron thick silicon carbide substrates.

TABLE 4

| Expansion Height | Temperature | Hold Time | Expansion Speed |
|---|---|---|---|
| 8 mm | 60 C. | 30 seconds | 10 mm/sec |

A designed experiment was carried out that investigated the effect that changing the laser power in three X-direction passes would have on the distance between a pattern area crack line and the die polyimide ring (SL remaining) and pattern area good die (die in the area of a pattern in the die street for which there was no observed offset breaking). Ten legs were run and the results of the experiment showed that changing laser power in the X direction passes would not, by itself, have any statistically significant benefit on street pattern cracking.

Twelve additional tests were then run which involved increasing laser power, reducing the second pass/path laser power, adding one additional pass in the X direction, reducing the added pass scan speed, increasing the added pass scan speed, adding five microns of laser compensation, using a breaking sequence of X first then Y, shrinking the anvil distance and breaking order from the bottom to top, and having the X direction laser parameters follow the Y direction laser parameters. The best results on 1.5 wafers were found where the laser power was reduced on the second pass, one additional pass at 0.04 W was added, the scan speed of the additional pass was reduced, and where laser compensation at 5 microns was employed.

Three additional silicon carbide wafers were then processed using the identified parameters yielding a reduction in die failures from cracks due to pattern in the X direction die streets from 1428 PPM to 159 PPM, a statistically significant result. The combination of the changes to the parameters that involved by lasering changes and breaking changes was unexpected and surprising, particularly when the original testing indicated that changing laser power had no statistically significant effect on reducing yield loss due to uncontrolled lateral die cracking at the pattern areas on the wafer.

The resulting X-die street pattern parameters are found in Tables 5-8 below:

Table 5 includes the set of determined lasering parameters used for both 100 micron thick and 200 micron thick silicon carbide substrates that resulted from the foregoing experimentation:

TABLE 5

| | | | Focus | Scan | | | Laser | Focus | Scan |
|---|---|---|---|---|---|---|---|---|---|
| | | | Height | Speed | | | Power | Height | speed |
| Path | Wavelength | Power (W) | (um) | (mm/s) | Path | Wavelength | (W) | (um) | (mm/s) |
| X0 | 1064 nm | 0.18 | −26 | 525 | Y0 | 1064 nm | 0.23 | −26 | 510 |
| X1 | 1064 nm | 0.12 | −19 | 525 | Y1 | 1064 nm | 0.23 | −21 | 510 |
| X2 | 1064 nm | 0.04 | −13 | 150 | Y2 | 1064 nm | 0.04 | −13 | 150 |
| X3 | 1064 nm | 0.18 | −14 | 525 | Y3 | 1064 nm | 0.23 | −17 | 510 |
| | | | | | Y4 | 1064 nm | 0.23 | −14 | 510 |

Table 6 includes the set of determined breaking parameters for use with the breaking system for about 100 micron thick silicon carbide substrates. The breaking sequence involves breaking the Y direction streets first followed by breaking the X direction streets second.

TABLE 6

| | Over Travel Height | Anvil Distance | Chopper Drop |
|---|---|---|---|
| Direction | (mm) | (ratio multiplier) | Speed (mm/s) |
| X | 1.23 | 0.39 | 20 mm/s |
| Y | 1.21 | 0.39 | 20 mm/s |

Table 7 includes the set of determined breaking parameters for use with the breaking system for about 200 micron thick silicon carbide substrates. The breaking sequence involves breaking the Y direction streets first followed by breaking the X direction streets.

TABLE 7

| | Over Travel Height | Anvil Distance | Chopper Drop |
|---|---|---|---|
| Direction | (mm) | (ratio multiplier) | Speed (mm/s) |
| X | 1.14 | 0.39 | 20 mm/s |
| Y | 1.12 | 0.39 | 20 mm/s |

Table 8 is the set of determined expansion parameters for use with the expansion system for both about 100 micron and about 200 micron thick silicon carbide substrates.

TABLE 8

| Expansion Height | Temperature | Hold Time | Expansion Speed |
|---|---|---|---|
| 8 mm | 60 C. | 30 seconds | 10 mm/sec |

The ability to singulate silicon carbide substrates using stealth dicing while substantially reducing lateral and uncontrolled cracking due to patterned areas in the die streets may lead to additional advantages through the elimination of processing steps used in sawing. For example, the elimination of high pressure water jets and pressurized air on the top surface of the wafer during singulation can lead to no observable solderable top metal peeling defects being observed post-stealth dicing. The elimination of chipping from a saw blade may allow for shrinking of the die streets and corresponding wafer density increase. Other process improvements may be observed as the substrates per hour or wafers per hour that can be processed using stealth dicing may measurably higher in contrast with other processes like dual saw blade cutting (2.4 wafers per hour), Sakasa-blade cutting (9 wafers per hour), or laser full cutting (8 wafers per hour). Since the stealth dicing process does not involve use of water, surfactant chemical, or any blade consumables, a significant reduction of cost of ownership compared to a dual sawing process could also be achieved.

In places where the description above refers to particular implementations of method of singulating semiconductor substrates and implementing components, sub-components, methods and sub-methods, it should be readily apparent that a number of modifications may be made without departing from the spirit thereof and that these implementations, implementing components, sub-components, methods and sub-methods may be applied to other methods of singulating semiconductor substrates.

What is claimed is:

1. A method of singulating silicon carbide comprising:
providing a silicon carbide substrate comprising a thickness; and
in a plurality of X-direction die streets:
irradiating the silicon carbide substrate in an X-direction with a laser beam focused at a first focal point a first distance into the thickness in a first X-pass;
irradiating the silicon carbide substrate in the X-direction with the laser beam focused at a second focal point a second distance into the thickness in a second X-pass;
irradiating the silicon carbide substrate in the X-direction with the laser beam focused at a third focal point a third distance into the thickness in a third X-pass;
irradiating the silicon carbide substrate in the X-direction with the laser beam focused at a fourth focal point a fourth distance into the thickness in a fourth X-pass; and
in a plurality of Y-direction die streets:
irradiating the silicon carbide substrate in a Y-direction with the laser beam focused a first focal point a first distance into the thickness in a first Y-pass;
irradiating the silicon carbide substrate in a Y-direction with the laser beam focused a second focal point a second distance into the thickness in a second Y-pass;
irradiating the silicon carbide substrate in a Y-direction with the laser beam focused a third focal point a third distance into the thickness in a third Y-pass;
irradiating the silicon carbide substrate in a Y-direction with the laser beam focused a fourth focal point a fourth distance into the thickness in a fourth Y-pass;
irradiating the silicon carbide substrate in a Y-direction with the laser beam focused a fifth focal point a fifth distance into the thickness in a fifth Y-pass; and
breaking the silicon carbide substrate in the X-direction and in the Y-direction along the plurality of X-direction die streets and the plurality of Y-direction die streets, respectively, using an anvil; and
expanding a tape coupled to the silicon carbide substrate to separate a plurality of die from the silicon carbide substrate.

2. The method of claim 1, wherein the first distance in the first X-pass is further into the thickness than the second distance in the second X-pass, the second distance in the second X-pass is further into the thickness than the third distance in the third X-pass, and the fourth distance in the fourth X-pass is further into the thickness than the third distance in the third X-pass.

3. The method of claim 1, wherein the first distance in the first X-pass is −26 microns, the second distance in the second X-pass is −19 microns, the third distance in the third X-pass is −13 microns, and the fourth distance in the fourth X-pass is −14 microns.

4. The method of claim 1, wherein:
the first distance in the first Y-pass is further into the thickness than the second distance in the second Y-pass;
the second distance in the second Y-pass is further into the thickness than the third distance in the third Y-pass;
the fourth distance in the fourth Y-pass is further into the thickness than the third distance in the third Y-pass; and
the fourth distance in the fourth-Y-pass is further into the thickness than the fifth distance in the fifth Y-pass.

5. The method of claim 1, wherein the first distance in the first Y-pass is −26 microns, the second distance in the second Y-pass is −21 microns, the third distance in the third Y-pass is −13 microns, the fourth distance in the fourth Y-pass is −17 microns, and the fifth distance in the fifth Y-pass is −14 microns.

6. The method of claim 1, wherein a scan speed used in the first Y-pass, the second Y-pass, the fourth Y-pass, and the fifth Y-pass is 510 mm/second and a scan speed used in the third Y-pass is 150 mm/second.

7. The method of claim 1, wherein a scan speed used in the first X-pass, the second X-pass, and the fourth X-pass is 525 mm/second and a scan speed used in the third X-pass is 150 mm/second.

8. The method of claim 1, wherein:
a laser power used in the first X-pass and the fourth X-pass is 0.18 W;
a laser power used in the second X-pass is 0.12 W;
a laser power used in the third X-pass is 0.04 W;
a laser power used in the first Y-pass, the second Y-pass, the fourth Y-pass, and the fifth Y-pass is 0.23 W; and
a laser power used in the third Y-pass is 0.04 W.

9. A method of singulating silicon carbide comprising:
providing a silicon carbide substrate comprising a thickness; and
in a plurality of X-direction die streets, irradiating the silicon carbide substrate in an X-direction with a laser beam focused at a focal point a distance into the thickness in four X-passes;
in a plurality of Y-direction die streets, irradiating the silicon carbide substrate in a Y-direction with the laser beam focused a focal point a distance into the thickness in five Y-passes;
breaking the silicon carbide substrate first in the Y-direction and then in the X-direction an along the plurality of X-direction die streets and the plurality of Y-direction die streets, respectively, using an anvil at a predetermined over travel height, an anvil distance of 0.39 mm, and a chopper drop speed of 20 mm/second; and
expanding a tape coupled to the silicon carbide substrate to separate a plurality of die from the silicon carbide substrate at a temperature of 60 C.

10. The method of claim 9, wherein when the thickness of the silicon carbide substrate is 100 microns, the predetermined over travel height is 1.23 mm for the X-direction die streets and 1.21 mm for the Y-direction die streets.

11. The method of claim 9, wherein when the thickness of the silicon carbide substrate is 200 microns, the predetermined over travel height is 1.14 mm for the X-direction die streets and 1.12 mm for the Y-direction die streets.

12. The method of claim 9, wherein expanding the tape further comprises expanding at an expansion height of 8 mm, an expansion speed of 10 mm/second, and a hold time of 30 seconds.

13. A method of singulating silicon carbide comprising:
providing a silicon carbide substrate comprising a thickness; and
in a plurality of X-direction die streets, irradiating the silicon carbide substrate in an X-direction with a laser beam focused at a focal point a depth into the thickness in a predetermined number of X-passes, each X-pass of the predetermined number of X-passes having a different laser spot diameter;
in a plurality of Y-direction die streets, irradiating the silicon carbide substrate in a Y-direction with the laser beam focused a focal point a depth into the thickness in a predetermined number of Y-passes, each Y-pass of the predetermined number of Y-passes having a different laser spot diameter;
breaking the silicon carbide substrate first in the Y-direction and then in the X-direction along the plurality of X-direction die streets and the plurality of Y-direction die streets, respectively, using an anvil; and
expanding a tape coupled to the silicon carbide substrate to separate a plurality of die from the silicon carbide substrate.

14. The method of claim 13, wherein, in the X-direction, a first laser spot diameter of a first X-pass is larger than a second laser spot diameter of a second X-pass and a third laser spot diameter of a third X-pass is smaller than a fourth laser spot diameter of a fourth X-pass.

15. The method of claim 13, wherein, in the Y-direction, a first laser spot diameter of a first Y-pass is larger than a second laser spot diameter of a second Y-pass, a third laser spot diameter of a third Y-pass is smaller than a fourth laser spot diameter of a fourth Y-pass, and a fifth laser spot diameter of a fifth Y-pass is smaller than the fourth laser spot diameter of the fourth Y-pass.

16. The method of claim 13, wherein a first depth of a first X-pass is −26 microns, a second depth of a second X-pass is −19 microns, a third depth of a third X-pass is −13 microns, and a fourth depth of a fourth X-pass is 14 microns.

17. The method of claim 13, wherein a first depth of a first Y-pass is −26 microns, a second depth of a second Y-pass is −21 microns, a third depth of a third Y-pass is −13 microns, a fourth depth of a fourth Y-pass is −17 microns, and a fifth depth of a fifth Y-pass is −14 microns.

18. The method of claim 14, wherein the fourth laser spot diameter of the fourth X-pass generates a modified region in portions of the plurality of X-direction die streets not covered by a pattern.

19. The method of claim 14, wherein the fourth laser spot diameter of the fourth X-pass burns a pattern present in portions of the plurality of X-direction die streets.

20. The method of claim 14, wherein the first laser spot diameter, second laser spot diameter, and third spot diameter generate a modified region in portions of the plurality of X-direction die streets covered by a pattern.
